(19) United States
(12) Patent Application Publication
(10) Pub. No.: US 2008/0180160 A1
(43) Pub. Date: Jul. 31, 2008

(54) HIGH VOLTAGE DUAL GATE CMOS SWITCHING DEVICE AND METHOD

(75) Inventor: Andreas Augustin, Muenchen (DE)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES AG, MUNICH (DE)

(21) Appl. No.: 11/669,594

(22) Filed: Jan. 31, 2007

(51) Int. Cl. H03K 17/687; H01L 27/07; H01L 21/8234

(52) U.S. Cl. 327/436; 257/392; 438/279; 257/E27.029; 257/E21.616

(57) ABSTRACT

A dual gate drain extension field effect transistor assembly comprises a first FET device having a source, a gate and a drain extension region. The first FET device's gate is electrically coupled to a constant voltage source. A second FET device has a source, a drain, and a gate, and the second FET's drain is electrically to the first FET's source.

### FIELD OF THE INVENTION

The invention relates generally to semiconductor devices, and more specifically in one embodiment to an improved dual gate high voltage CMOS device providing improved switching power characteristics.

### BACKGROUND

Semiconductor devices such as transistors and integrated circuits are typically formed on a substrate of a semiconducting material, using processes such as etching, lithography, and ion implantation to form various structures and materials on the substrate. A single field-effect transistor (FET), for example, may require a dozen or more steps to form implanted source and drain regions, an insulating layer, and a gate separated from the channel region by the insulating region.

In operation, doped source and drain regions are coupled to a circuit such that a voltage signal applied to the gate region controls the conductivity or resistivity of a channel region physically located between the source and drain regions. The conductivity of the channel region is based on an electric field created by potential applied to the gate, relative to the voltages present at the source and drain. Field effect transistors are sometimes described as being voltage-controlled resistors for this reason, and are used for applications such as amplifiers, signal processing, and control systems.

Field effect transistors are also very common in digital logic circuit such as in computer processors, memory, and other digital electronics. The voltage applied to the gate in such applications is typically intended to either turn off the FET completely or turn it on completely, such that the FET operates more like a switch than a variable resistor. For such applications, the switching speed, device size, leakage current, and a variety of other parameters are designed to provide the desired device size and operating characteristics, within the limitations of available technology. One such limitation is the voltage that can be applied between the various terminals of a FET device before the voltage overcomes the semiconductor material and damages the FET, known as the breakdown voltage. Some applications benefit from management of multiple device characteristics, such as battery-powered communication devices that desirably handle large breakdown voltages, such as high voltages coupled to the drain, while simultaneously considering the switching power needed to change the state of the FET.

### BRIEF DESCRIPTION OF THE FIGURES

FIG. 1 illustrates a typical field effect transistor, consistent with the prior art.

FIG. 2 illustrates a field effect transistor having a drain extension region including a lightly doped drain region, consistent with the prior art.

FIG. 3 illustrates a field effect transistor having a drain extension region including a heavily doped drain region embedded in an elongated lightly doped drain region, consistent with the prior art.

FIG. 4 illustrates a field effect transistor having a drain extension region including a lightly doped drain region extending around an insulating region, consistent with the prior art.

FIG. 5 illustrates a dual gate field effect transistor having a drain extension region including a lightly doped drain extension region extending around an insulating region, consistent with an example embodiment of the invention.

FIG. 6 is a schematic diagram indicating the electrical connection configuration and electric operational function of the dual gate drain extension device of FIG. 5, consistent with an example embodiment of the invention.

### DETAILED DESCRIPTION

In the following detailed description of example embodiments of the invention, reference is made to specific example embodiments of the invention by way of drawings and illustrations. These examples are described in sufficient detail to enable those skilled in the art to practice the invention, and serve to illustrate how the invention may be applied to various purposes or embodiments. Other embodiments of the invention exist and are within the scope of the invention, and logical, mechanical, electrical, and other changes may be made without departing from the subject or scope of the present invention. Features or limitations of various embodiments of the invention described herein, however essential to the example embodiments in which they are incorporated, do not limit other embodiments of the invention or the invention as a whole, and any reference to the invention, its elements, operation, and application do not limit the invention as a whole but serve only to define these example embodiments. The following detailed description does not, therefore, limit the scope of the invention, which is defined only by the appended claims.

One example embodiment of the invention provides a dual gate drain extension field effect transistor assembly, an integrated circuit comprising such an assembly, and methods of making and operating such an assembly. The example embodiment comprises a substrate doped in a first type such as p-type silicon, and a source region formed in the substrate and comprising a semiconductor material doped in a second type such as n-type silicon. A drain extension region is formed in the substrate and comprises a semiconductor material doped in the second type, and a middle region is formed in the substrate comprising a semiconductor material doped in the second type. A middle region is formed between the source region and drain extension region, and is separated from the source and drain regions by channel regions. A first gate is separated by an insulator such as a silicon dioxide layer from a channel region separating the drain extension region from the middle region; and a second gate is separated by an insulator from a channel region separating the middle region from the source region.

The first gate is coupled to a continuous voltage source such that it is always on. Capacitance between the drain extension region and the first gate therefore need not be overcome as the gate's state does not change during operation, and the assembly's state is switched by the second gate. This example provides improved voltage handling capability along with reduced switching power, and provides a compact drain extension configuration for efficient use of semiconductor die space.

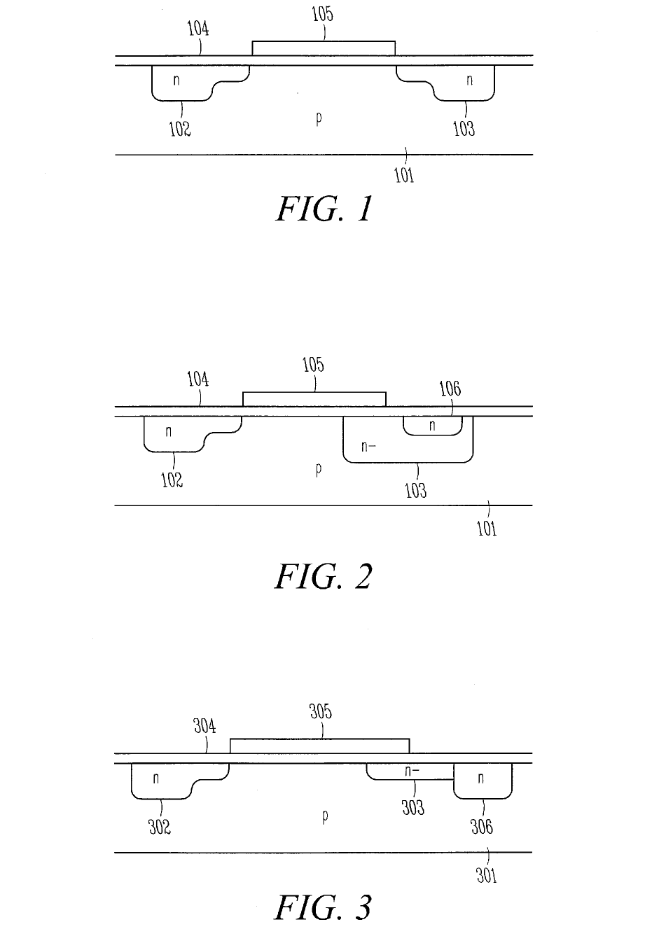

FIG. 1 illustrates a typical field effect transistor, consistent with the prior art. A semiconductor substrate has a p-type region, such as a silicon substrate doped with boron, as shown at 101. Two n-type semiconductor regions are formed at 102 and 103, such as by ion implantation of a dopant such as phosphorous. These two regions are known as the source and the drain, as one region is used as the source of charge carriers conducted across the channel region, while the other drains the conducted charge carriers. An insulating layer, such as a semiconductor oxide, is formed at 104, separating the channel region of the p-type substrate located between the source 102 and drain 103 from a metal gate 105. The gate is therefore electrically isolated from the source, drain, and channel region of the substrate, and influences conduction across the channel region between the source and drain by an electric field generated as a result of application of voltage to the gate 105.

With no voltage applied to the gate, the channel region of the substrate does not conduct, and essentially no electricity is able to flow between the source 102 and the drain 103. Even with application of increasingly large voltage across the source 102 and drain 103, only a small amount of leakage current is able to flow across the channel region unless an excessive voltage known as the breakdown voltage is applied across the source and the drain, and the transistor is destroyed. When a potential is applied to the gate and the source-drain voltage is small, the channel region acts like a resistor that varies in resistance with the applied voltage, enabling the FET to operate essentially as a voltage-controlled resistor. When larger voltages are applied across the source and drain, or when the gate voltage is relatively near the source or drain voltages, the FET will be turned almost completely on or off, acting more like a switch than a resistor as is common in digital electronic applications.

While FET devices such as that of FIG. 1 are by far the most common FET devices, they do not handle large supply voltages well, particularly at small geometries. When voltages in the range of tens of volts are applied across the drain and another terminal of the FET of FIG. 1, the FET may reach breakdown voltage and fail.

FIG. 2 illustrates a field effect transistor having an extended drain, consistent with the prior art. The general structure of the FET is similar to that of FIG. 1, including a p-type silicon substrate 201 doped with boron, and an n-type region 102 formed by implanting phosphorous into the substrate. An insulating layer 204 such as silicon oxide separates the substrate from the gate 105, which is formed of a conductive material such as polysilicon or metal.

The drain region 103 comprises both a lightly doped n-type region doped with phosphorous, and a more heavily doped n-type region 106, doped with a higher concentration of phosphorous. This extended drain region shown at 103 and 106 is one example of an extended drain, which characterized what is known in the art as a drain-extended metal oxide semiconductor FET, or a DEMOS FET.

The extended drain region serves to provide the FET with the ability to handle significantly higher drain voltages than a FET such as that of FIG. 1 would be able to handle using similar geometry or semiconductor process limitations. This is useful in applications such as where a voltage regulator is integrated into an integrated circuit, or in other applications such as communications amplifiers where high drain voltages may be supplied.

The drain region of FIG. 2 is not aligned at the edge of the gate as is the drain of the FET in FIG. 1, but extends somewhat under the gate. A relatively large voltage can be applied to the drain at 106 because part of the applied drain voltage drops in a depletion layer formed in the more lightly doped drain region 103, such that the electric field seen by the gate remains at a voltage below the gate-drain breakdown voltage. The source remains aligned to the gate, such as where the source is self-aligned by implanting the phosphorous dopant used to form the source by using the gate or a gate with a mask layer as a portion of the mask. The gate-to-source breakdown voltage therefore remains the same as before.

In one example, a 1.5 Volt process using process parameters and semiconductor device technologies to produce traditional FET devices such as that of FIG. 1 can incorporate drain extended FET devices such as that of FIG. 2 using similar geometry in the same process to allow sustained source-drain breakdown voltages of 8 Volts or higher. This enables a 1.5 Volt semiconductor device operating with a 5 Volt power supply to employ on-chip voltage regulation, and to perform other such functions using relatively high voltage power or input signals.

Another example of a drain extended FET is shown in FIG. 3, which again is substantially similar to the FET of FIG. 1 except for a modified drain configuration. A p-type doped semiconductor substrate 301 is implanted with ions such as phosphorous to produce source 302, which in this example is self-aligned with the gate 305. A drain 303 is formed with a lightly doped to moderately doped n-type ion such as phosphorous. The source, drain, and channel region of the substrate are separated from conductive gate 305 by an insulating layer 304, such as silicon oxide. The drain in this example also comprises a more heavily doped n-type semiconductor region 306, which serves as the drain contact area.

In operation, the extended n-type drain region 303 includes a depletion region over which a part of the applied relatively high drain voltage drops, allowing significantly higher drain voltages without breakdown than would be possible using the configuration of FIG. 1 with the same semiconductor processes and relative geometry.

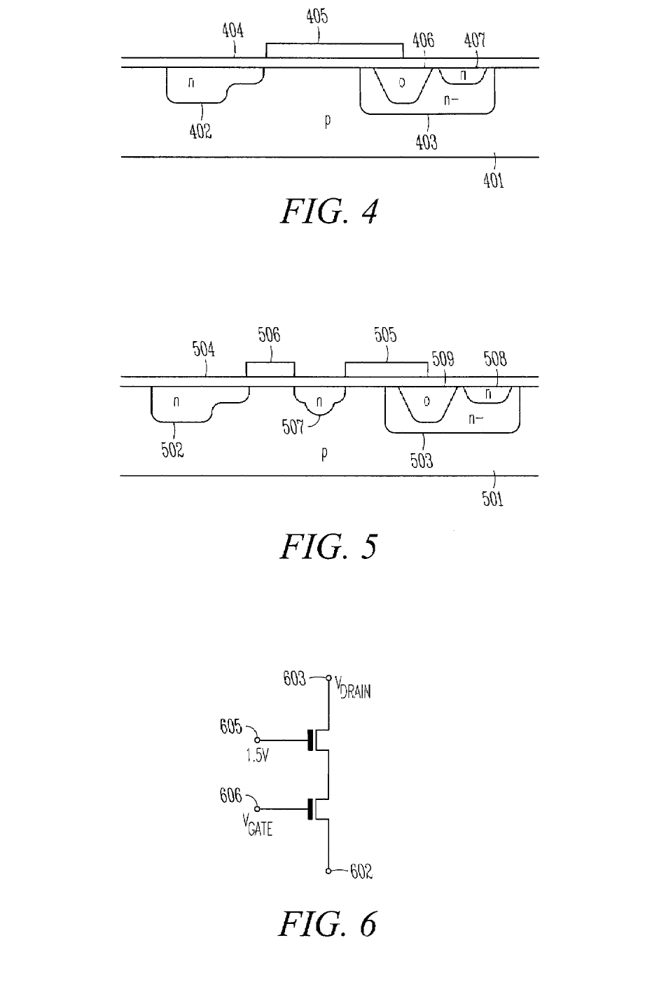

The extended drain region and depletion region over which a high drain voltage drops is formed in some further embodiments by contouring the semiconductor path of the drain using insulators or other materials, such as is shown in FIG. 4. The drain extended FET of FIG. 5 comprises a p-type substrate 401 and a source 402 similar to those of the other example transistors, and includes an insulating layer and an isolated gate 405 much like the other FET examples. The drain region 403 comprises a lightly to moderately n-type doped region, such as phosphorous doped silicon, with an insulating oxide region 406 and a more heavily n-type doped region 407 embedded therein. The drain contact is made at 407, and the depletion region formed in the more lightly n-type doped material 403 provides a drop in voltage applied to the drain in operation, enabling the extended drain region to handle application of relatively high voltages.

The more lightly doped n-type region 403 extends under and around the insulating material 406, which in some embodiments comprises a silicon oxide but in other embodiments comprises another relatively nonconductive material. The current path from the drain contact at 407 to the channel region of the substrate follows along the contour of the insulating region, extending the effective length of the drain path between the drain contact and the channel region. The current flows through the more lightly doped n-type drain material 403 down the drain contact side of the insulating region 406, and near the bottom of the insulating region before flowing up the channel side of the insulating region until it reaches the conductive portion of the channel region near the gate 405. The current path is therefore significantly extended for the amount of space used in a semiconductor layout, as the effective drain current path flows both down form the channel region of the substrate to reach under the insulating region 406 and back up the other side of the insulating region to reach the drain contact.

But, this configuration has a relatively high gate capacitance, due in part to the proximity of the gate to the drain region 403. Other drain extension FET devices such as those of FIGS. 2 and 3 share this problem, and require significant switching current to overcome this capacitance and require significant voltages to change state. This contributes to significant power consumption in each drain extension FET device that changes state, which can have a significant impact on power consumed in portable devices such as battery powered communication devices or in devices that are in continuous operation or use a significant number of drain extension FET devices.

The present invention provides in one example embodiment a dual gate drain extension FET device, as shown in FIG. 5. In this example device, a substrate 501 comprises a semiconductor such as silicon, doped with a material such as boron to produce a p-type semiconductor. A source 502 is formed in the substrate, such as by ion implantation with phosphorous ions, and comprises an n-type doped semiconductor material. A drain 503 is formed by similar processes, but in this example is a more lightly doped n-type semiconductor material, such as silicon having a lower concentration per volume of phosphorous atoms than the source 502. An insulating layer 504, such a silicon oxide or another insulating material, is formed over at least certain regions of the substrate known as the channel regions, to electrically isolate the channel regions and the other parts of the substrate such as the doped drain region 503 from a first gate 505 and a second gate 506. The first and second gates here are separated by some distance, and the space between the first gate and second gate in the substrate is filled with a middle n-type region 507

The resulting electrical device is shown in schematic form in FIG. 6. The drain region 503 corresponds to the drain voltage connection 603, and the n-type source region is represented by connection 602. The first gate 505 is represented by connection 605, which in this example is coupled to a fixed bias voltage of 1.5 volts. The second gate 506 is represented by gate voltage input connection 606, and is used to control the switched state of the cascade biased FET pair. Although the cascoded FET devices are in this example are n-channel devices having a p-type doped channel region and n-type doped source and drain regions, other embodiments include p-channel FET devices having n-type doped channel regions and p-type doped source and drain regions.

In operation, the first gate 505 of FIG. 5 and 605 of FIG. 6 is coupled to a bias voltage to bring the drain extended FET device it controls to an on state. The relatively large underlap of the extended drain region 503, also seen at 403 of FIG. 4, results in significant capacitance between the gate and the drain, making the switching current required to change the state of the first FET controlled by the gate shown at 505 significant. By constantly biasing the FET controlled by gate 505, the FET stays on and does not incur the high switching power consumed during a state change, while retaining the high voltage capability and compact geometry of the drain extension as shown in FIG. 4.

The FET device formed by source 502, gate 506, and middle n-type region 507 is then used as a cascode coupled device to selectively couple the drain 503 to the source 502 by varying the control voltage signal applied to the gate 506. As the first FET device controlled by the biased gate 505 is always on, only the gate voltage applied to the second gate 506 need change to change state of the cascoded FET device shown in FIG. 5. Because the state of the FET device formed by gate 505, drain 503, and middle n-type region 504 does not change state, the relatively high capacitance between the drain 503 and the gate 505 need not be overcome to change the state of the cascode device, and the energy needed to overcome the capacitance is not expended.

The resulting high voltage capability along with low power consumption realized by the drain extension dual gate cascode FET device of FIGS. 5 and 6 provides significant advantages where relatively large voltages are used and power consumption is important. In one example application, an integrated circuit operating at 1.5 volts is coupled to a 5 volt power supply, and receives 5 volt input logic signals. Because the semiconductor process for the integrated circuit is designed to handle 1.5 volt logic signals, input voltages of 5 volts may exceed the safe operating voltage of traditional transistors formed using the semiconductor process, and cause breakdown or failure of the transistor. Incoming 5 v logic signals can however be switched using the same semiconductor process via the drain extended cascode FET configuration of FIG. 5 by receiving them in the drain extension of the first FET constantly biased on via gate 505 or 605, and switching the incoming voltage signal via the second FET controlled by gate 506 or 606.

Similarly, on-chip voltage regulation for the integrated circuit to produce the 1.5 volt power signal needed to power its digital logic from the supplied 5 v voltage power signal can be performed using circuits incorporating various embodiments of the invention, such as the dual gate drain extension FET device illustrated in FIG. 5. Such devices can also be used to handle high voltage signals such as a line driver for communication systems such as a digital subscriber line (DSL), which operates at 12 volts, or for wireless communication amplifiers such as cellular telephone equipment.

The constant voltage applied to the gate 505 is in some embodiments an integrated circuit's power supply voltage, such as the 1.5 volt regulated power signal in the on-chip voltage regulator example above. The constant voltage need not be applied when the dual gate drain extension transistor device is not being used, such as when a portion of an integrated circuit is powered down for power management purposes, but is generally maintained on when the dual gate drain extension transistor device assembly is in use.

The cascode FET arrangement shown in the drawing of FIGS. 5 and 6 also provides improved gain, as the drain extension FET controlled by gate 605 serves as the load for the lower FET controlled by gate 606. The source voltage of the drain extension FET is held relatively constant, resulting in a relatively constant input drain voltage for the lower FET of FIG. 6. This significantly reduces the feedback capacitance (Miller capacitance) from the lower FET's drain to gate, permitting the lower FET to operate with lower Miller capacitance and higher input impedance and gain. Analog gain is also improved in some embodiments, as the submicron halo or pocket region implants often used to control short channel effects in the channel region can be reduced or eliminated on the drain extension side of the channel.

The increased voltage handling capability of the drain extension also provides greater immunity to device breakdown or destruction as a result of shocks, or electrostatic discharge. Because the drain extension region of the example structure illustrated in FIG. 5 is approximately 20 volts or higher in the example shown there, the voltage handling capability is improved by an amount approaching an order of magnitude and the susceptibility of the integrated circuit to electric shock is significantly reduced. Drain extension FET devices are therefore considered self-protecting against electrostatic discharge, and do not require special input or output device structures for ESD protection, resulting in a chip area advantage over prior technologies.

The field effect transistor device structure example presented here, having a split gate forming two FET devices cascode coupled, including a device having a drain extension region to handle high voltages controlled by a biased gate connection, provides a number of advantages as described herein. The relatively small space taken by the structure provides compact and efficient use of space on a silicon substrate, the drain extension region provides the ability to handle high drain voltages, the cascode configuration provides improved gain, and the split gate with a biased first gate provides low switching power consumption relative to other drain extension FET devices. This combination of features results in an example embodiment that is well-suited for a variety of applications, and that has distinct advantages over prior art devices.

Although specific embodiments have been illustrated and described herein, it will be appreciated by those of ordinary skill in the art that any arrangement that achieve the same purpose, structure, or function may be substituted for the specific embodiments shown. The example of FIG. 5 is adapted to the environment of FIG. 4, but similar advantages can be realized by embodiments of the invention that adapt the invention as described and claimed to other environments such as are shown in FIGS. 2 and 3. This application is intended to cover any adaptations or variations of the example embodiments of the invention described herein. It is intended that this invention be limited only by the claims, and the full scope of equivalents thereof.

1. An integrated circuit, comprising:
a first FET device having a source, a gate and a drain extension region, the first FET device's gate electrically coupled to a constant voltage source; and
a second FET device having a source, a drain, and a gate, the second FET's drain electrically to the first FET's source.

2. The integrated circuit of claim 1, wherein the drain of the first FET device and the source of the second FET device comprise a single continuous region of doped semiconductor material.

3. The integrated circuit of claim 1, wherein the first and second FET devices comprise a part of a voltage regulator.

4. The integrated circuit of claim 1, wherein the gate of the first FET device is coupled to a continuous voltage source.

5. The integrated circuit of claim 1, wherein the first FET device is operable to receive a higher drain voltage than the second FET device.

6. A method of operating a circuit, comprising:
receiving a high voltage in a first FET device having a source, a gate and a drain extension region;
providing a constant voltage to the gate of the first FET device such that the first device is constantly on; and
switching the state of a second FET device having a source, a drain, and a gate, the second FET's drain electrically to the first FET's source, such that the received high voltage signal is conducted through the first FET device and switched via the second FET device.

7. The method of operating a circuit of claim 6, wherein the drain of the first FET device and the source of the second FET device comprise a single continuous region of doped semiconductor material.

8. The method of operating a circuit of claim 6, wherein the high voltage received in the first FET device is higher than a safe operating voltage of the second transistor.

9. A method of making a circuit, comprising:
forming a first FET device having a source, a gate and a drain extension region, the first FET device's gate electrically coupled to a constant voltage source; and
a second FET device having a source, a drain, and a gate, the second FET's drain electrically to the first FET's source.

10. The method of making a circuit of claim 9, wherein the circuit comprises a part of an integrated circuit such that the first FET device is designed to receive a voltage greater than a safe operating voltage of the second FET device.

11. The method of making a circuit of claim 9, further comprising forming an oxide region embedded in the drain extension region configured to lengthen the current path through the drain extension region.

12. A dual gate drain extension field effect transistor assembly, comprising:
a substrate doped in a first type;
a source region formed in the substrate and comprising a semiconductor material doped in a second type;
a drain extension region formed in the substrate and comprising a semiconductor material doped in the second type;
a middle region formed in the substrate and comprising a semiconductor material doped in the second type, the middle region formed between the source region and drain extension region and separated from the source and drain extension regions by channel regions;
a first gate separated by an insulator from a channel region separating the drain region from the middle region; and
a second gate separated by an insulator from a channel region separating the middle region from the source region.

13. The dual gate drain extension field effect transistor assembly of claim 12, wherein the first dopant type comprises n-type and the second dopant type comprises p-type.

14. The dual gate drain extension field effect transistor assembly of claim 12, further comprising an oxide region embedded in the drain extension region configured to lengthen the current path through the drain.

15. The dual gate drain extension field effect transistor assembly of claim 12, wherein the first gate is coupled to a constant voltage source.

16. The dual gate drain extension field effect transistor assembly of claim 12, wherein the first gate and second gate are electrically isolated from each other.

17. A dual gate drain extension field effect transistor assembly, comprising:
a first FET device having a source, a gate and a drain extension region, the first FET device's gate electrically coupled to a constant voltage source; and
a second FET device having a source, a drain, and a gate, the second FET's drain electrically to the first FET's source.

18. The dual gate drain extension field effect transistor assembly of claim 17, wherein the drain of the first FET device and the source of the second FET device comprise a single continuous region of doped semiconductor material.

19. The dual gate drain extension field effect transistor assembly of claim 17, wherein the drain extension region of the first transistor comprises a fist section that is relatively heavily doped and a second section that is relatively lightly doped.

20. The dual gate drain extension field effect transistor assembly of claim 17, further comprising an insulating region embedded in the drain extension region of the first FET device, configured to lengthen the current path through the drain extension region.

21. The dual gate drain extension field effect transistor assembly of claim 17, wherein the switching capacitance of the dual gate drain extension field effect transistor assembly is lower than the switching capacitance of the first FET device.
